(19) United States
(12) Patent Application Publication
(10) Pub. No.: US 2006/0186935 A1
(43) Pub. Date: Aug. 24, 2006

(54) Circuit and method for generating boost element drive signals for semiconductor memory devices with mode register set signals

(75) Inventors: Sung-Min Hwang, Yeosu-si (KR); Kye-Hyun Kyung, Yongin-si (KR)

Correspondence Address: F. CHAU & ASSOCIATES, LLC, 130 WOODBURY ROAD, WOODBURY, NY, 11797, US

(73) Assignee: Samsung Electronics Co., LTD., Suwon-si (KR)

(21) Appl. No.: 11/338,287

(22) Filed: Jan. 24, 2006

(30) Foreign Application Priority Data
Jan. 25, 2005 (KR) 2005-6551

(51) Int. Cl. H03B 1/00

(52) U.S. Cl. 327/112

(57) ABSTRACT

Disclosed herein is a circuit and method for generating a boost element drive signal in a semiconductor memory device with a mode register set signal. The boost element drive signal generation circuit includes a preliminary drive signal generation unit and a level shifter. The preliminary drive signal generation unit generates a preliminary drive signal in response to a group of mode setting signals. The mode setting signal group is provided from a mode register set. The level shifter generates the boost element drive signal in response to the preliminary drive signal. The pull-up voltage of the boost element drive signal is level-shifted relative to a pull-up voltage of the preliminary drive signal. According to the boost element drive signal generation circuit of the present invention, the activation instant of a boost element drive signal is controlled by a mode setting signal group. Therefore, the boost element drive signal is activated after a boost voltage is stabilized. Therefore, in a semiconductor memory device to which the boost element drive signal generation circuit of the present invention is applied, leakage current flowing through a normal inverter that has an input terminal for receiving the output signal of a boost inverter is greatly decreased.

### CROSS-REFERENCE TO RELATED APPLICATION

This application claims the priority of Korean Patent Application No. 10-2005-0006551, filed on Jan. 25, 2005, in the Korean Intellectual Property Office, the disclosure of which is incorporated by reference herein in its entirety.

### BACKGROUND OF THE INVENTION

1. Field of the Invention

The present invention relates generally to a signal generation circuit and method for a semiconductor memory device and, more particularly, to a circuit and method for generating a boost element drive signal for a semiconductor memory device. The circuit generates a boost element drive signal used to control the driving of boost elements pulled up to a boost voltage in an initial power up state.

2. Description of the Related Art

In a semiconductor memory device, a boost voltage Vpp is used to improve the driving capability of respective devices or to prevent a voltage drop at the time of transmitting data. In this case, the boost voltage Vpp is a voltage boosted by pumping a charge from an externally applied supply voltage Vcc and by storing the charge in a capacitor. Therefore, when the semiconductor memory device is powered up, the boost voltage Vpp is stabilized only if a certain period has elapsed from the instant at which the supply voltage Vcc was applied.

In a conventional semiconductor memory device, there may frequently occur the case in which the output signal N20 of a boost inverter 10 is applied to the input terminal of a normal inverter 30, as shown in FIG. 1. Further, the boost inverter 10 is pulled up to the boost voltage Vpp, and the normal inverter 30 is pulled up to the supply voltage Vcc. In this case, when the boost voltage Vpp is lower than the supply voltage Vcc, the voltage applied to the input terminal of the normal inverter 30 may be a voltage existing between a ground voltage Vss and the supply voltage Vcc. At this time, both a PMOS transistor 31 and an NMOS transistor 33 of the normal inverter 30 are turned on, so that a current path is formed. In order to prevent the formation of a current path in the normal inverter 30, a boost element drive signal /VPPDR for driving the boost inverter 10 is required to be activated after a certain period has elapsed from the instant at which the supply voltage Vcc was applied. Typically, a semiconductor memory device includes a boost element drive signal generation circuit for generating the boost element drive signal /VPPDR.

FIG. 2 is a view showing a conventional circuit 100 for generating a boost element drive signal. The boost element drive signal generation circuit 100 of FIG. 2 level-shifts an initialization signal PVCCH using a shifting means 110, and inverts the level-shifted signal using an inverter 120, thus generating the boost element drive signal /VPPDR. The initialization signal PVCCH transits from logic Low to logic High in response to the increase of the supply voltage Vcc to a reference voltage level or higher.

However, even at the point at which the supply voltage Vcc increases to the reference voltage level or higher, the boost voltage Vpp occasionally becomes lower than the supply voltage Vcc (refer to t1 of FIG. 3). Therefore, the conventional boost element drive signal generation circuit 100 is in that the boost element drive signal /VPPDR may be asserted to logic Low when the boost voltage Vpp is lower than the supply voltage Vcc.

### SUMMARY OF THE INVENTION

In accordance with one aspect of the present invention, there is provided a circuit for generating a boost element drive signal for a semiconductor memory device. The boost element drive signal drives a boost element pulled up to a boost voltage. The boost element drive signal generation circuit of the present invention includes a preliminary drive signal generation unit and a level shifter. The preliminary drive signal generation unit generates a preliminary drive signal in response to a group of mode setting signals. The group of mode setting signals is provided from a mode register set. The level shifter generates the boost element drive signal in response to the preliminary drive signal. The boost element drive signal has a pull-up voltage that is level-shifted relative to a pull-up voltage of the preliminary drive signal.

In accordance with one aspect of the present invention, there is provided a method of generating a boost element drive signal for a semiconductor memory device. In the boost element drive signal generation method, a group of mode setting signals is received. The group of mode setting signals is provided from a mode register set. Then, a preliminary drive signal is generated in response to the group of mode setting signals. The boost element drive signal is generated in response to the preliminary drive signal. The boost element drive signal has a pull-up voltage that is level-shifted relative to a pull-up voltage of the preliminary drive signal.

### BRIEF DESCRIPTION OF THE DRAWINGS

FIG. 1 shows a typical array of inverters, and shows the case in which an output signal of a boost inverter is applied to an input terminal of a normal inverter;

FIG. 2 shows a conventional circuit for generating a boost element drive signal;

FIG. 3 shows the activation instant of the boost element drive signal of FIG. 2;

FIG. 4 shows a circuit for generating a boost element drive signal for a semiconductor memory device according to an exemplary embodiment of the present invention;

FIG. 5 shows a preliminary drive signal generation unit of FIG. 4 in detail;

FIG. 6 shows an example of the implementation of a signal combination means of FIG. 5;

FIG. 7 shows the activation instant of a boost element drive signal in the boost element drive signal generation circuit of FIG. 4; and

FIG. 8 shows a flowchart of a method of generating a boost element drive signal according to an exemplary embodiment of the present invention.

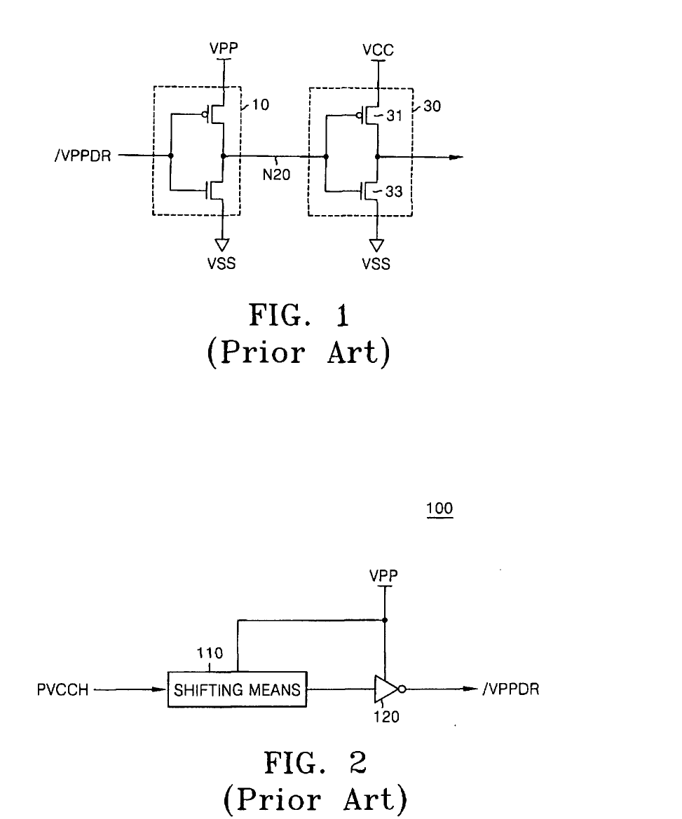

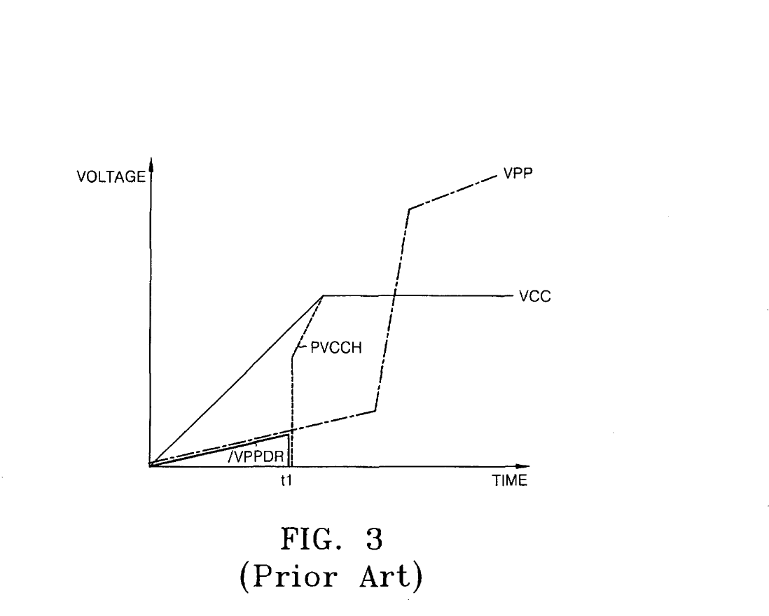

### DETAILED DESCRIPTION OF THE PREFERRED EMBODIMENTS

Exemplary embodiments of the present invention will be described in detail with reference to the attached drawings. The drawings use the same reference numerals throughout to designate the same or similar components.

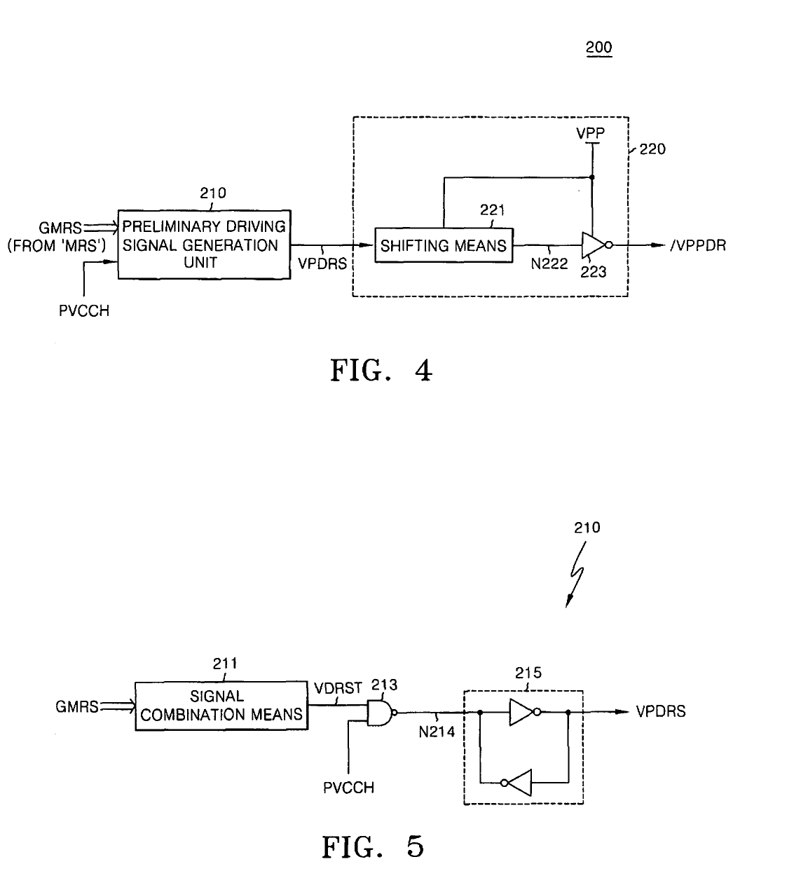

FIG. 4 shows a circuit for generating a boosting element drive signal for a semiconductor memory device according to an exemplary embodiment of the present invention. A boost element drive signal /VPPDR, provided from a boost element drive signal generation circuit 200, drives a boost element such as a boost inverter 223 that is pulled up to a boost voltage Vpp. The boost element drive signal generation circuit 200 includes a preliminary drive signal generation unit 210 and a level shifter 220. The preliminary drive signal generation unit 210 generates a preliminary drive signal VPDRS in response to a group of mode setting signals GMRS. The mode setting signal group GMRS is provided from a mode register set (MRS) (not shown) included in the semiconductor memory device to which the present invention is applied. There is at least one signal in the mode setting signal group GMRS, which is a signal automatically activated when the semiconductor memory device is powered up.

The setting of the mode register set can be performed at the latter half of the sequence of a power up process starting from the instant at which the supply voltage Vcc is applied. The boost voltage Vpp is sufficiently stabilized at the instant at which at least one signal in the mode setting signal group GMRS is activated.

In a semiconductor memory device of the present invention, operating modes (for example, a burst type, a burst length, and the latency of a Column Address Strobe [CAS] signal) are set through the setting of the mode register set. Further, a TEST mode for allowing a vendor to test a chip, and a JEDEC mode for allowing a user to determine a burst type or a burst length, etc. may be selected through the setting of the mode register set. The GMRS may include signals used to control an auto-precharge function, or the enabling of a Delayed Locked Loop (DLL).

The preliminary drive signal generation unit 210 can be enabled in response to a predetermined initialization signal PVCCH. In this case, the initialization signal PVCCH is a signal that makes a transition when a supply voltage Vcc having increased to a predetermined reference level or higher is sensed.

FIG. 5 shows the preliminary drive signal generation unit 210 of FIG. 4 in detail. The preliminary drive signal generation unit 210 includes a signal combination means 211, a logic means 213 and a latch means 215. The signal combination means 211 combines the mode setting signals of the GMRS and provides the combination results as a drive start signal VDRST.

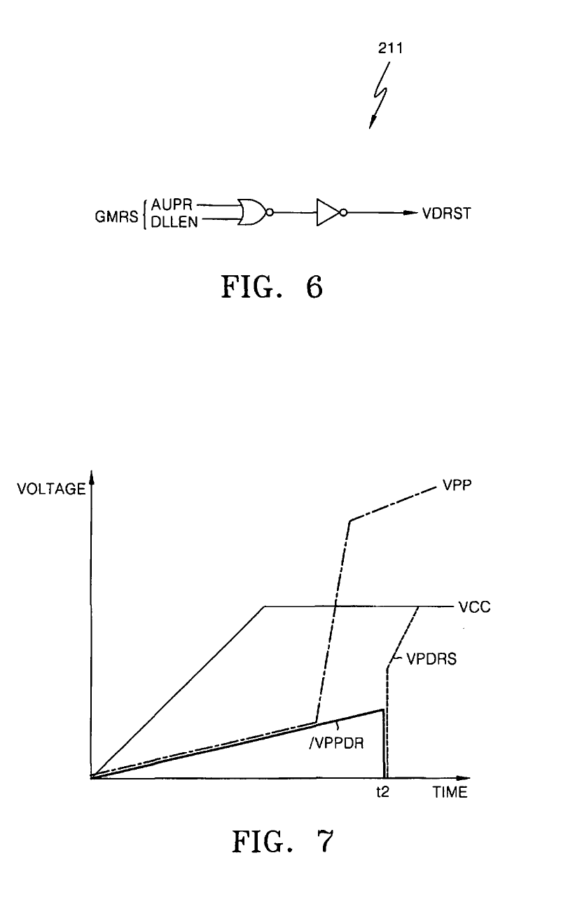

An example of an implementation of the signal combination means 211 is shown in FIG. 6. The signal combination means 211 performs a logical OR operation on an auto-precharge signal AUPR and a DLL enable signal DLLEN, which are signals from the mode setting signal group GMRS, and generates the drive start signal VDRST. Therefore, the drive start signal VDRST is activated to logic High when the auto-precharge signal AUPR or the DLL enable signal DLLEN is activated to logic High.

Referring again to FIG. 5, the logic means 213 is enabled in response to the initialization signal PVCCH. Further, the logic means 213 generates an output signal responding to the drive start signal VDRST. The logic means 213 can be implemented with a NAND gate for performing a logical NAND operation on the initialization signal PVCCH and the drive start signal VDRST.

The latch means 215 latches an output signal N214 of the logic means 213 and provides latch results as the preliminary drive signal VPDRS.

Consequently, the preliminary drive signal VPDRS is activated to logic High after the initialization signal PVCCH makes a transition to logic High and the mode setting signal group GMRS is generated.

Referring again to FIG. 4, the level shifter 220 includes a shifting means 221 and an inverter 223. The shifting means 221 level-shifts the pull-up voltage of the preliminary drive signal VPDRS. Further, the inverter 223 inverts the logic level of the output signal N222 of the shifting means 221 and generates the boost element drive signal /VPPDR.

Therefore, the pull-up voltage of the boost element drive signal /VPPDR is level-shifted relative to the pull-up voltage of the preliminary drive signal VPDRS.

Thus, according to an embodiment of the present invention, in the boost element drive signal generation circuit 200, at the instant at which the boost element drive signal /VPPDR is activated, it is controlled by the mode setting signal group GMRS. The mode setting signal group GMRS is activated after the boost voltage Vpp is sufficiently stabilized, as described above. Therefore, the boost element drive signal /VPPDR is activated after the boost voltage Vpp is stabilized. That is, at the instant at which the boost element drive signal /VPPDR is activated to logic Low, the boost voltage Vpp is higher than the supply voltage Vcc (refer to t2 of FIG. 7).

Due to the boost element drive signal generation circuit 200, even if the output signal of a boost inverter is applied to the input terminal of the normal inverter, the probability that the PMOS and NMOS transistors of a normal inverter may be simultaneously turned on is greatly decreased. Therefore, leakage current flowing through the normal inverter is greatly decreased.

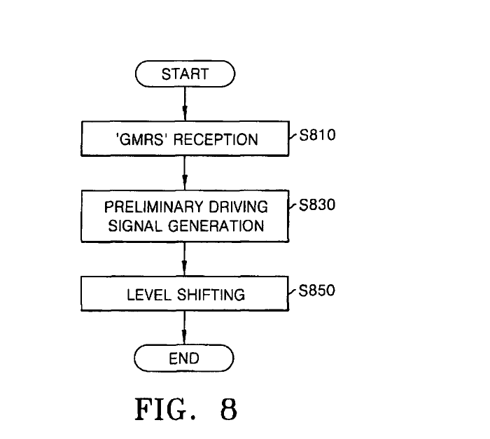

A method of generating a boost element drive signal using the boost element drive signal generation circuit 200 of FIG. 4 is shown in FIG. 8.

First, the mode setting signal group GMRS is received at MRS reception step S810. The preliminary drive signal VPDRS is generated in response to the mode setting signal group GMRS at preliminary step S830.

Then, the boost element drive signal /VPPDR is generated in response to the preliminary drive signal VPDRS at level shifting step S850. The pull-up voltage of the boost element drive signal /VPPDR is level-shifted relative to the pull-up voltage of the preliminary drive signal VPDRS, as described above.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. For example, in the present specification, an embodiment in which the activation instant of a boost element drive signal is delayed due to a mode setting signal group is shown and described. However, it is apparent to those skilled in the art that the activation instant of a boost element drive signal can also be delayed due to another power-up control signal. In this case, the power-up control signal is activated last according to a sequence so as to power up the semiconductor memory device. Therefore, the technical scope of protection of the present invention is defined by the technical spirit of the accompanying claims.

What is claimed is:

1. A boost element drive signal generation circuit for generating a boost element drive signal for a semiconductor memory device, the circuit comprising:
a preliminary drive signal generation unit for generating a preliminary drive signal in response to a group of mode setting signals which is provided from a mode register set; and
a level shifter for generating the boost element drive signal in response to the preliminary drive signal, wherein the boost element drive signal has a pull-up voltage that is level-shifted relative to a pull-up voltage of the preliminary drive signal.

2. The boost element drive signal generation circuit according to claim 1, wherein the level shifter comprises a shifting means for level-shifting the pull-up voltage of the preliminary drive signal.

3. The boost element drive signal generation circuit according to claim 1, wherein the preliminary drive signal generation unit is enabled in response to a predetermined initialization signal that makes a transition when a supply voltage having increased to a reference level or higher is sensed.

4. The boost element drive signal generation circuit according to claim 3, wherein the preliminary drive signal generation unit comprises:
a logic means enabled in response to the initialization signal to generate an output signal responding to at least one signal in the mode setting signal group; and
a latch means for latching the output signal of the logic means and providing latch results as the preliminary drive signal.

5. A method of generating a boost element drive signal for a semiconductor memory device, the method comprising the steps of:
receiving a group of mode setting signals, which is provided from a mode register set;
generating a preliminary drive signal in response to the group of mode setting signals; and
generating the boost element drive signal in response to the preliminary drive signal, wherein the boost element drive signal has a pull-up voltage that is level-shifted relative to a pull-up voltage of the preliminary drive signal.

6. A boost element drive signal generation circuit for generating a boost element drive signal for a semiconductor memory device, the circuit comprising:
a preliminary drive signal generation unit for generating a preliminary drive signal in response to the generation of a predetermined power-up control signal, wherein the power-up control signal is activated last according to a sequence to power up the semiconductor memory device; and
a level shifter for generating the boost element drive signal in response to the preliminary drive signal, wherein the boost element drive signal has a pull-up voltage that is level-shifted relative to a pull-up voltage of the preliminary drive signal.

7. The boost element drive signal generation circuit for generating a boost element drive signal for a semiconductor memory device of claim 6, wherein the power-up control signal is generated after detecting a minimum supply voltage and completion of reset and initialization functions of the semiconductor memory device.

8. A method of generating a boost element drive signal for a semiconductor memory device, the method comprising the steps of:
receiving a predetermined power-up control signal that is activated last according to a sequence to power up the semiconductor memory device;
generating a preliminary drive signal in response to the power-up control signal; and
generating the boost element drive signal in response to the preliminary drive signal, wherein the boost element drive signal has a pull-up voltage that is level-shifted relative to a pull-up voltage of the preliminary drive signal.

9. The method of generating a boost element drive signal for a semiconductor memory device according to claim 8, wherein the power-up control signal is generated after detecting a minimum supply voltage and completion of reset and initialization functions of the semiconductor memory device.
